(19) United States
(12) Patent Application Publication
(10) Pub. No.: US 2010/0295601 A1
(43) Pub. Date: Nov. 25, 2010

(54) SEMICONDUCTOR DEVICE

(75) Inventors: Nobuyoshi OKUDA, Shiga-ken (JP); Shunsuke KOBAYASHI, Kyoto-fu (JP); Nobukazu SUZUKI, Shiga-ken (JP)

Correspondence Address: Studebaker & Brackett PC, One Fountain Square, 11911 Freedom Drive, Suite 750, Reston, VA, 20190, US

(73) Assignee: MURATA MANUFACTURING CO., LTD., Kyoto-fu (JP)

(21) Appl. No.: 12/782,605

(22) Filed: May 18, 2010

(30) Foreign Application Priority Data
May 22, 2009 (JP) 2009-124401

(51) Int. Cl. H03K 17/56

(52) U.S. Cl. 327/419

(57) ABSTRACT

A semiconductor device (antenna switch) causes a switch circuit to perform a switching operation by using a logic circuit. The switch circuit and the logic circuit are formed on a single semiconductor substrate and a shield conductor is provided or arranged directly over the logic circuit. The shield conductor can have an air bridge structure and can be connected to a ground terminal.

### CROSS REFERENCE TO RELATED APPLICATIONS

This application claims priority to Japanese Patent Application No. JP 2009-124401, filed May 22, 2009, the entire contents of which are incorporated herein by reference in their entirety.

### BACKGROUND

1. Field of the Invention

The present invention relates to a semiconductor device, and more particularly, to a semiconductor device that includes a switch circuit and a logic circuit.

2. Description of the Related Art

Antenna switch modules are known, which are semiconductor devices arranged directly under an antenna of a mobile telephone or the like, such semiconductor devices being structured so as to cause a switch circuit including a transistor to perform a switching operation by using a logic circuit.

In Japanese Unexamined Patent Application Publication No. 2004-350068 (hereinafter, “the ′068 application”), an antenna switch circuit is described in which semiconductor substrates are used. Chips respectively constituting an antenna switch circuit and an antenna switch decoder circuit are formed on separate substrates and are connected to each other using wire bonding.

### SUMMARY

An embodiment of a semiconductor device consistent with the claimed invention includes a switch circuit and a logic circuit. The switch circuit and the logic circuit is formed on a single semiconductor substrate and a shield conductor is provided directly over the logic circuit.

In one aspect of the semiconductor device, because the switch circuit and the logic circuit are formed on a single semiconductor substrate, the size and the cost of the device can be reduced and since the shield conductor is provided or arranged directly over the logic circuit, even when a high-frequency electrical signal is radiated from the switch circuit, since the radiated signal is allowed to escape through the shield conductor, there is no risk of erroneous operations occurring in the logic circuit.

In another aspect, a semiconductor device can be obtained in which the adverse effect on a logic circuit of a high-frequency electrical signal radiated from a switch circuit can be suppressed without sacrificing reduction of the size and cost of the device.

Other features, elements, characteristics and advantages of the present invention will become more apparent from the following detailed description of preferred embodiments of the present invention (with reference to the attached drawings).

### BRIEF DESCRIPTION OF THE DRAWINGS

FIG. 1 is a block diagram illustrating an outline configuration of a semiconductor device according to a preferred embodiment of the invention.

FIG. 2 is a circuit diagram of the semiconductor device.

FIG. 3 is an explanatory diagram illustrating the positional relationship between the individual elements of the semiconductor device.

FIG. 4 is a sectional diagram illustrating an exemplary logic circuit of the semiconductor device.

FIGS. 5A to 5C are each an plan view of a shield conductor arranged over the semiconductor device.

### DETAILED DESCRIPTION

In the antenna switch circuit described in the ′068 application, since the antenna switch circuit and the decoder circuit are formed on separate substrates and integrated with each other by being connected by wire bonding, the overall size of the device is increased, it is necessary to include a process for connecting the circuits to each other, and the cost is increased.

Consequently, it has been considered to form a switch circuit and a logic circuit, which controls the switch circuit, on a single semiconductor substrate. However, if the circuits are arranged close to each other, for example, in cases where a signal having a high electrical power (high frequency) of 35 dBm is output when transmission is performed in the global system for mobile communications (GSM), errors occur due to the fact that when the signal having the high electrical power (high frequency) is supplied to the switch circuit, part of the signal is radiated to the logic circuit. If the radiated part of the signal affects the logic circuit, there is a risk that the logic circuit will perform an erroneous operation.

The effect of such a radiated signal on the logic circuit can be reduced by increasing the number of transistors used in the switch circuit, by increasing the separation of the switch circuit and the logic circuit, and/or by increasing the size of the IC; however, in such a case, the size of the device can no longer be reduced and the advantage of forming the two circuits on a single substrate is lost.

The embodiments of a semiconductor device described hereafter can suppress the adverse effect on a logic circuit of a high-frequency electrical signal radiated from a switch circuit without sacrificing reduction of the size and cost of the device.

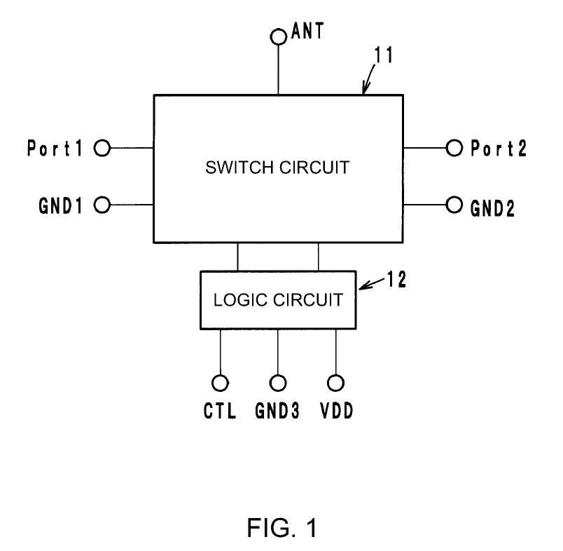

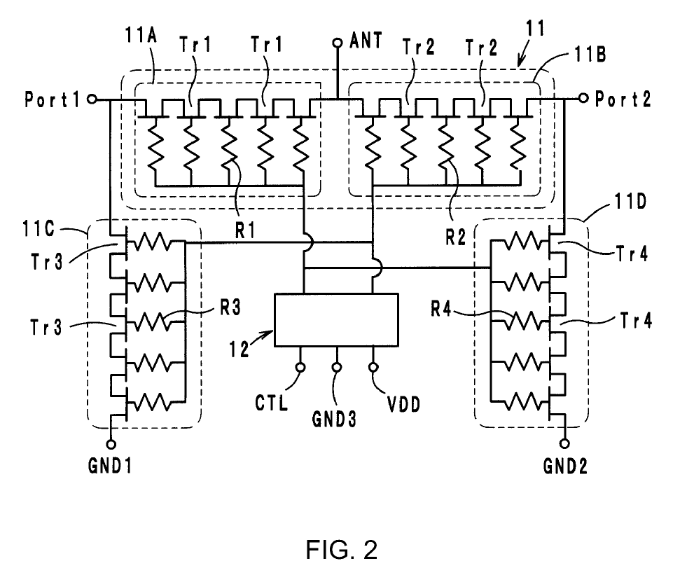

With reference to FIGS. 1 and 2, a semiconductor device according to an embodiment is shown as a single-pole double-throw switch, and includes a switch circuit 11 and a logic circuit 12 and can be arranged directly below an antenna of a mobile telephone or the like.

In more detail, the switch circuit 11 is composed of switch circuits 11A, 11B, 11C and 11D, which respectively have transistors Tr1, Tr2, Tr3 and Tr4 and resistors R1, R2, R3 and R4, and is equipped with an antenna terminal ANT, signal terminals Port1 and Port2, and ground terminals GND1 and GND2. The logic circuit 12 is configured using a predetermined circuit that causes the switch circuit 11 to perform a switching operation and is equipped with a control terminal CTL, a power source terminal VDD and a ground terminal GND3.

In the above single-pole double-throw switch (antenna switch), when a signal for connecting the antenna terminal ANT and the signal terminal Port1 is input to the logic circuit 12 from the control terminal CTL, the logic circuit 12 outputs a control signal and each of the transistors Tr1 and Tr4 of the switch circuits 11A and 11D is switched on while each of the transistors Tr2 and Tr3 of the switch circuits 11B and 11C remains in a switched-off state. Conduction occurs between the antenna terminal ANT and the signal terminal Port1 due to the switch circuit 11A being switched on. Since the switch circuit 11D is in a switched-on state and is connected to the ground through the ground terminal GND2, the signal, which leaks toward the signal terminal Port2, is allowed to escape to the outside through the ground terminal GND2.

On the other hand, when a signal for connecting the antenna terminal ANT and the signal terminal Port2 to each other is input to the logic circuit 12 from the control terminal CTL, each of the transistors Tr2 and Tr3 of the switch circuits 11B and 11C are switched on and each of the transistors Tr1 and Tr4 of the switch circuits 11A and 11D are in a switched-off state. Since the switch circuit 11B is in a switched-on state, conduction occurs between the antenna terminal ANT and the signal terminal Port2. Since the switch circuit 11C is in a switched-on state and is connected to the ground through the ground terminal GND1, the signal, which leaks toward the signal terminal Port1, is allowed to escape to the outside through the ground terminal GND1.

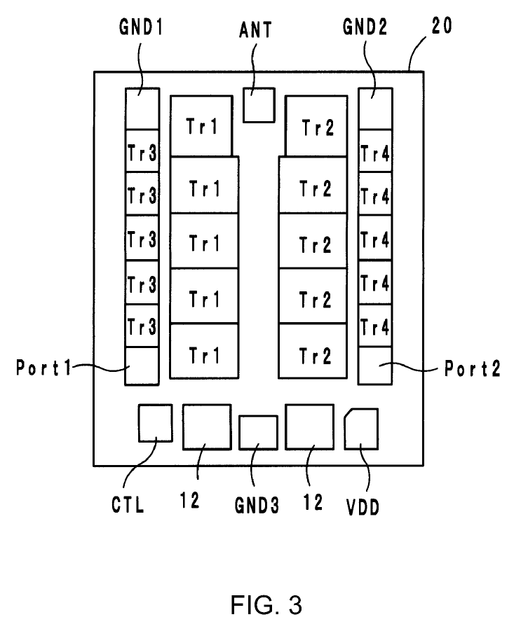

As shown in FIG. 3, the transistors Tr1, Tr2, Tr3, Tr4 and the terminals ANT, Port1, Port2, GND1 and GND2 are arranged on a semiconductor substrate 20. In this embodiment, each of the switch circuits is configured using five transistors, although the number of transistors may be changed in accordance with the required output. Furthermore, the logic circuit 12 can be arranged on a lower portion of the semiconductor substrate 20 to be bisected by the ground terminal GND3.

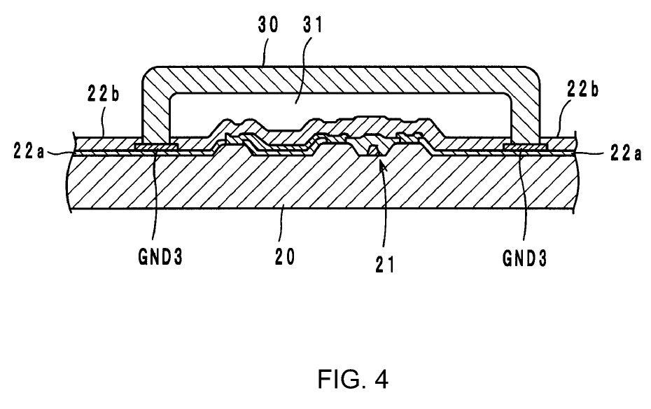

With reference now to FIG. 4, a shield conductor 30 can be arranged directly over the bisected logic circuit 12 to cover both parts of the bisected logic circuit 12. As illustrated in FIG. 4, regarding the sectional structure of the logic circuit 12, for example, a device 21, such as a transistor, which constitutes part of the logic circuit 12, is formed on part of the surface of a gallium arsenide semiconductor substrate 20. Electrodes, such as the ground terminal GND3, are formed on a protective layer 22a using gold or titanium, and thereafter a protective layer 22b is formed over the entire structure. The protective layers 22a and 22b are composed of silicon nitride, silicon oxide, a polyimide or the like. The shield conductor 30 is composed of a conductor, such as gold, and is formed to be electrically connected to the ground terminal GND3 via an opening in the protective layer 22b and have an air bridge structure.

The concept of an air bridge structure is described in detail in Japanese Unexamined Patent Application Publication No. H7-321425, for example. The shield conductor 30 can be formed by coating a resist onto the surface of the protective layer 22b, drying the resist, forming a metal film on the resist over the protective layer 22b by plating or the like and then removing the resist. The hollow remaining after the resist has been removed forms a space 31. Alternatively, the resist may be allowed to remain as is. Furthermore, rather than forming an air bridge structure, the shield conductor 30 can be formed directly over the protective layer 22b.

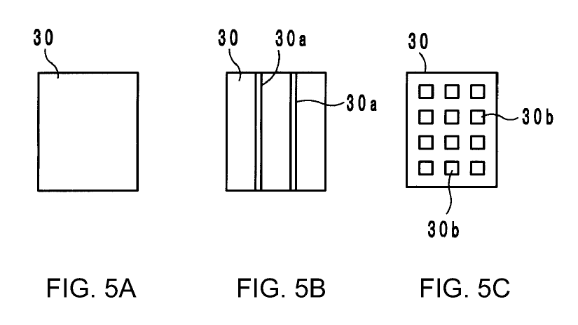

The shield conductor 30 can be shaped so as to entirely cover the logic circuit 12 as illustrated in FIG. 5A, slits 30a can be formed therein as illustrated in FIG. 5B, or a multiplicity of openings 30b can be formed therein in a mesh-like pattern as illustrated in FIG. 5C. Moreover, the size (area) of each provided shield conductor 30 can be approximately equal to the size (area) of each part of the bisected logic circuit 12 illustrated in FIG. 3.

In the semiconductor device (antenna switch module/composite module) having the above structure, since the switch circuit 11 and the logic circuit 12 are formed on the single semiconductor substrate 20, a reduction in the size of the device is achieved because the wiring is shortened and furthermore since time is not spent performing a packaging operation, a reduction in cost can also be achieved. Moreover, since the shield conductor 30 can be arranged directly over the logic circuit 12, even when a high-frequency electrical signal is radiated from the switch circuit 11, there is no risk of an erroneous operation occurring in the logic circuit 12 because the radiated signal is allowed to escape from the shield conductor 30 through the ground terminal GND3.

The shield conductor 30 does not necessarily have to be connected to the ground terminal GND3, but a more excellent shielding effect can be obtained when the shield conductor 30 is connected to the ground. Provided that a radiated high-frequency electrical signal is allowed to escape, the shield conductor 30 can be connected to the control terminal CTL or the power source terminal VDD.

Moreover, forming the slits 30a or the openings 30b in the shield conductor 30 makes it easy to remove the resist when forming the air bridge structure and the strength of the shield conductor and the capability of the shield conductor to resist being damaged by the atmosphere are improved. Furthermore, the floating capacitance generated between the shield conductor 30 and the logic circuit 12 becomes small and control operations are stabilized. In the case where the slits 30a are formed, the width dimension of the slits 30a can be set equal to or less than half the wavelength of a high-frequency signal to prevent intrusion of high-frequency signals into the logic circuit 12.

In addition, when the shield conductor 30 has an air bridge structure, since the space 31 having a dielectric constant of one is formed between the shield conductor 30 and the logic circuit 12, the floating capacitance generated therebetween can be made small and control operations can be stabilized.

Furthermore, referring again to FIG. 3, by arranging the ground terminals GND1 and GND2 of the switch circuit 11 and the ground terminal GND3 of the logic circuit 12 at different positions and separated from each other on the semiconductor substrate 20, intrusion of noise generated in the switch circuit 11 into the logic circuit 12 can be prevented. Moreover, by dividing the logic circuit 12 into two parts, arranging the ground terminal GND3 between the two parts of the logic circuit 12 and arranging the control terminal CTL and the power-source terminal VDD on either side of the ground terminal GND3, the operation of making electrical connections to these terminals from the outside can be simplified.

The semiconductor device according to the claimed invention is not limited to the above-described exemplary embodiment and various modifications are possible within the scope of the gist of the invention.

For example, the number of each type of electronic device and the number of terminals provided on the semiconductor substrate and the positional relationships therebetween are arbitrary. Furthermore, the materials detailed in the embodiment are just illustrative examples.

As described above, an embodiment of the present invention has utility as a semiconductor device equipped with a switch circuit and a logic circuit and can suppress an adverse effect of a high-frequency electrical signal radiated from a switch circuit on a logic circuit without sacrificing reduction of the size and cost of the device.

While exemplary embodiments have been described above, it is to be understood that variations and modifications will be apparent to those skilled in the art without departing from the scope and spirit of the claimed invention. The scope of the invention, therefore, is to be determined solely by the following claims and their equivalents.

What is claimed is:

1. A semiconductor device comprising:
a switch circuit; and
a logic circuit;
wherein the switch circuit and the logic circuit are formed on a single semiconductor substrate, and a shield conductor is provided directly over the logic circuit.

2. The semiconductor device according to claim 1,
wherein the shield conductor is connected to ground.

3. The semiconductor device according to claim 1,
wherein the logic circuit includes a control terminal for allowing control of the switch circuit and a power source terminal for supplying electrical power to the logic circuit and the switch circuit; and
wherein the shield conductor is connected to the control terminal and/or the power source terminal.

4. The semiconductor device according to claim 1,
wherein a slit, an opening or a mesh-like pattern is formed in the shield conductor.

5. The semiconductor device according to claim 2,
wherein a slit, an opening or a mesh-like pattern is formed in the shield conductor.

6. The semiconductor device according to claim 3,
wherein a slit, an opening or a mesh-like pattern is formed in the shield conductor.

7. The semiconductor device according to claim 1,
wherein the shield conductor has an air bridge structure.

8. The semiconductor device according to claim 2,
wherein the shield conductor has an air bridge structure.

9. The semiconductor device according to claim 3,
wherein the shield conductor has an air bridge structure.

10. The semiconductor device according to claim 4,
wherein the shield conductor has an air bridge structure.

11. The semiconductor device according to claim 5,
wherein the shield conductor has an air bridge structure.

12. The semiconductor device according to claim 6,
wherein the shield conductor has an air bridge structure.

13. The semiconductor device according to claim 1,
wherein the shield conductor is formed on a surface of a protective layer formed on the semiconductor substrate.

14. The semiconductor device according to claim 2,
wherein the shield conductor is formed on a surface of a protective layer formed on the semiconductor substrate.

15. The semiconductor device according to claim 3,
wherein the shield conductor is formed on a surface of a protective layer formed on the semiconductor substrate.

16. The semiconductor device according to claim 4,
wherein the shield conductor is formed on a surface of a protective layer formed on the semiconductor substrate.

17. The semiconductor device according to claim 5,
wherein the shield conductor is formed on a surface of a protective layer formed on the semiconductor substrate.

18. The semiconductor device according to claim 6,
wherein the shield conductor is formed on a surface of a protective layer formed on the semiconductor substrate.

19. The semiconductor device according to claim 1,
wherein a ground terminal of the switch circuit and a ground terminal of the logic circuit are arranged at different positions on the semiconductor substrate.

20. The semiconductor device according to claim 2,
wherein a ground terminal of the switch circuit and a ground terminal of the logic circuit are arranged at different positions on the semiconductor substrate.
